(19) United States
(12) Patent Application Publication
(10) Pub. No.: US 2010/0294353 A1
(43) Pub. Date: Nov. 25, 2010

(54) CONDUCTIVE PASTE FOR SOLAR CELL ELECTRODE

(75) Inventor: Ryoichiro Takahashi, Kanagawa (JP)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/469,834

(22) Filed: May 21, 2009

(51) Int. Cl. H01L 31/0224; H01L 31/00; H01L 31/18

(52) U.S. Cl. 136/256; 438/98; 257/E31.124

(57) ABSTRACT

An electrode formed on the light-receiving side of photovoltaic cell, comprising conductive component, glass binder, and carbon fiber or metal fiber. By including a carbon fiber and a metal fiber, an electrode having a high aspect ratio can be formed, and improvement of optical conversion efficiency through an increase in light-receiving area can be expected.

### FIELD OF THE INVENTION

This invention relates to photovoltaic cell, and in particular, relates to improvement of conductive paste for electrode.

### TECHNICAL BACKGROUND OF THE INVENTION

One of the widely-used solar cells currently is silicon solar cells. The manufacturing process of the silicon solar cells typically includes the formation of electrode by use of conductive paste.

Generally, the conductive paste includes a conductive particle such as silver, inorganic binder such as glass frit, organic medium and optional other additives.

Since the electric generating capacity of solar cells increases as the light-receiving area thereof increases, it is preferable for the front electrode formed on the light-receiving area to have a narrow line width. However, if the line width is merely narrowed, a decrease in cross-sectional area of the electrode will end up increasing electrode resistance and will thus end up decreasing optical conversion efficiency. Therefore, there is a need to increase the height, that is, to increase the aspect ratio, while narrowing the line width.

JP2006-054374 discloses a method for forming an electrode having a high aspect ratio by forming a groove for electrode formation on a substrate and applying the aforementioned conductive paste under reduced pressure into this groove for electrode formation, thereby forming the electrode.

JP2007-019106 discloses a method for forming an electrode having a high aspect ratio by using a conductive paste containing an adjusted quantity of organic matter and silver powder and having suitable viscosity and thixotropy.

There is a need in the industry to improve conductive pastes that enable the production of an electrode with high aspect ratio.

### SUMMARY OF THE INVENTION

An aspect of the present invention is the production of a conductive paste with a high aspect ratio.

Another aspect of the present invention is an electrode formed on the light-receiving side of photovoltaic cell, comprising conductive component, glass binder, and carbon fiber or metal fiber.

Another aspect of the present invention is a method for forming an electrode of photovoltaic cell, comprising steps of: applying a conductive paste on the light-receiving side of a silicon wafer, the conductive paste comprising conductive powder, glass frit, carbon fiber or metal fiber, and organic medium; drying the applied paste; and firing the dried paste.

If the present invention is used, an electrode having a large aspect ratio can be formed, and improvement of optical conversion efficiency through an increase in the light-receiving area can be expected.

### BRIEF DESCRIPTION OF THE DRAWINGS

FIG. 1 is a process flow diagram illustrating the fabrication of an electrode of solar cell.

FIG. 2 is a boxplot of the relationship between the fiber content and the height of the formed electrode.

### DETAILED DESCRIPTION OF THE INVENTION

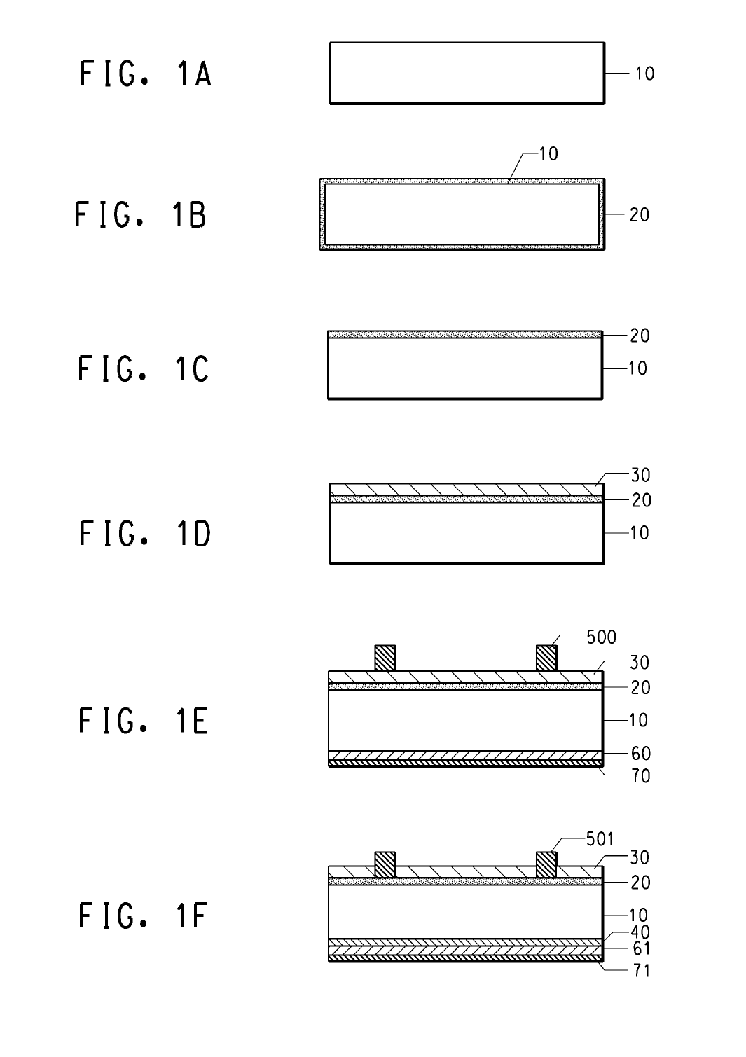

Referring to the FIG. 1, a typical embodiment of manufacturing process of Si photovoltaic cell is illustrated.

FIG. 1A shows a p-type silicon substrate, 10. In FIG. 1B, an n-type diffusion layer, 20, of the reverse conductivity type is formed by the thermal diffusion of phosphorus (P) or the like. Phosphorus oxychloride (POCl₃) is commonly used as the phosphorus diffusion source. In the absence of any particular modification, the diffusion layer, 20, is formed over the entire surface of the silicon substrate, 10. This diffusion layer typically has a sheet resistivity on the order of several tens of ohms per square, and a thickness of about 0.3 to 0.5 μm.

After protecting one surface of this diffusion layer with a resist or the like, as shown in FIG. 1C, the diffusion layer, 20, is removed from most surfaces by etching so that it remains only on one main surface. The resist is then removed using an organic solvent or the like.

Next, a silicon nitride film, 30, is formed as an anti-reflection coating on the n-type diffusion layer, 20, to a thickness of typically about 700 to 900 Å in the manner shown in FIG. 1D by a process such as plasma chemical vapor deposition (CVD).

As shown in FIG. 1E, a conductive paste (typically silver paste), 50, for the front (light-receiving side) electrode is screen printed then dried over the silicon nitride film, 30. In addition, a backside silver or silver/aluminum paste, 70, and an aluminum paste, 60, are then screen printed and successively dried on the backside of the substrate. Firing is then carried out in a furnace at a temperature of approximately less than 1000° C. for several seconds or for several minutes.

Consequently, as shown in FIG. 1F, aluminum diffuses from the aluminum paste into the silicon substrate, 10, as a dopant during firing, forming a p+ layer, 40, containing a high concentration of aluminum dopant. This layer is generally called the back surface field (BSF) layer, and helps to improve the energy conversion efficiency of the solar cell.

The aluminum paste is transformed by firing from a dried state, 60, to an aluminum back electrode, 61. The backside silver or silver/aluminum paste, 70, is fired at the same time, becoming a silver or silver/aluminum back electrode, 71. During firing, the boundary between the back side aluminum and the back side silver or silver/aluminum assumes an alloy state, and is connected electrically as well. The aluminum electrode accounts for most areas of the back electrode, owing in part to the need to form a p+ layer, 40. Because soldering to an aluminum electrode is impossible, a silver back electrode is formed over portions of the back side as an electrode for interconnecting solar cells by means of copper ribbon or the like. In addition, the front electrode-forming silver paste, 50, sinters and penetrates through the silicon nitride film, 30, during firing, and is thereby able to electrically contact the n-type layer, 20. This type of process is generally called “fire through.” This fired through state is apparent in layer 51 of FIG. 1F.

The present invention provides an improved conductive paste for the light-receiving electrode, which enables the formation of an electrode with high aspect ratio. One characteristic modification of the present invention resides in the addition of carbon fiber or metal fiber into the conductive paste.

The electrode can be manufactured by applying a conductive paste onto the silicon-based substrate. The components of the conductive paste are discussed herein below.

### (1) Conductive Powder

Conductive powder is dispersed in an organic medium that acts as a carrier for the functional phase. The conductive powder includes one or more of metal powder(s) selected from the group consisting of Ag, Pd, Ir, Cu, Ni, Al, Au, Su, Zn, Pt, Ru, Ti, and Co. Given the conductivity and the metal price, silver is preferable at present.

The conductive powder may preferably be coated or uncoated silver particles which are electrically conductive. When the silver particles are coated, they may be partially coated with a surfactant. The surfactant may be selected from, but is not limited to, stearic acid, palmitic acid, a salt of stearate, a salt of palmitate and mixtures thereof. Other surfactants may be utilized including lauric acid, palmitic acid, oleic acid, stearic acid, capric acid, myristic acid and linolic acid. The counter ion can be, but is not limited to, hydrogen, ammonium, sodium, potassium and mixtures thereof.

The particle shape of the conductive powder can be spherical or flake type. It is not especially limited in this present invention.

The particle size of the conductive powder is not subject to any particular limitation, although the average particle size [d50] of no more than 10 μm, and preferably no more than 3 μm, is desirable. The conductive powder preferably accounts for, but not limited to, 70 to 96 wt % of the conductive paste.

### (2) Glass Frit

The conductive paste of the present invention preferably contains an inorganic binder in the form of glass frit. Since the chemical composition of the glass frit is not important in the present invention, any glass frit can be used provided it is a glass frit used in electrically conductive pastes for electronic materials. For example, lead borosilicate glass is used preferably. Lead borosilicate glass is a superior material in the present invention from the standpoint of both the range of the softening point and glass adhesion. In addition, lead-free glass, such as a bismuth silicate lead-free glass, can also be used from a viewpoint of environment.

Although there are no particular limitations on the content of the inorganic binder in the form of the glass frit provided it is an amount that allows the object of the present invention to be achieved, it is 0.5 to 15.0 wt % and preferably 1.0 to 10.0 wt % based on the weight of the paste. If the amount of the inorganic binder is less than 0.5 wt %, adhesive strength may become inadequate. If the amount of the inorganic binder exceeds 15.0 wt %, problems may be caused in the subsequent soldering step due to floating glass and so on. In addition, the resistance value as a conductor also increases.

An average particle size of the glass frit (d50) in the range of 0.5-4.0 μm is preferred, and in the range of 0.7-3.0 μm is more preferred. An average surface area of the glass frit (SA) in the range of 5.4-7.0 m²/g is preferred. The softening point of the glass frit (Ts: second transition point of DTA) is preferred to be in the range of 450-650° C. for glass containing at least PbO. For glass containing at least Bi₂O₃, the Ts is preferred to be in the range of 450-650° C.

(3) Carbon Fiber and/or Metal Fiber

Carbon fiber and metal fiber (both called inorganic fiber hereafter) contribute to preservation of the shape of the conductive paste before drying or firing. Although the shape of a conventional paste not containing these inorganic fibers and only containing dispersed conductive powder and glass frit can be preserved to some extent, the shape breaks down and the aspect ratio decreases during the period from application or printing until drying or firing, or during firing. Since the paste containing the inorganic fiber maintains a high aspect ratio after application, the aspect ratio of the formed electrode can be improved. Furthermore, if the carbon fiber or the metal fiber is added with careful consideration given to the additive amount thereof, the resistance of the electrode itself will not increase as much. For the metal fiber in particular, the high conductivity of the fiber itself prevents a decrease in power generation efficiency resulting from the addition.

Another advantage of adding the inorganic fiber is that its presence inhibits excessive contraction during firing, and therefore avoids detachment of the electrode. Damage to the substrate can also be expected to decrease.

As a metal fiber, one type or two or more types of metal fiber from the group consisting of silver (Ag), gold (Au), platinum (Pt), palladium (Pd), titanium (Ti), alloys thereof can be mentioned. A commercially available metal fiber can be used, and a metal fiber having a shape and length adjusted with consideration given to applications for solar cell electrodes can also be used. It is preferable to use a metal fiber having a fiber diameter and a fiber length mentioned below.

The metal fiber can be a fiber coated on a surface thereof with metal. The concept of metal fiber in the present application includes not only a fiber consisting entirely of metal, but also includes a fiber coated on a surface thereof with metal. For example, when an expensive metal such as gold or platinum is used, a type of fiber comprising an inexpensive component such as polyester, polyamide, and polyolefin and coated with a metal on a surface thereof is more profitable than a type of fiber consisting entirely of expensive metal. There is no particular limitation on the method for manufacturing the fiber coated with the metal or on the material used inside. For example, art mentioned in JP H11 (1999)-117179 can be applied.

There are no particular limitations on the carbon fiber, but use of the following fiber diameter or fiber length is preferred. Among carbon fibers, a carbon fiber manufactured by a vapor-phase growth method is preferable in terms of thermal conductivity and cost. Such a fiber has the advantage that firing progresses easily because thermal conductivity is high, and such a fiber contributes to reduction of the manufacturing cost of solar cells. For example, VGCF, manufactured by Showa Denko K. K., can be used as the carbon fiber.

The inorganic fiber can have a shape comprising a trunk and a branch. Such a configuration further improves toughness of the electrode because a sintered metal layer and the inorganic fiber are more complexly intertwined, and contact area of the sintered metal layer and the inorganic fiber is thus increased.

The amount of the inorganic fiber contained is preferably 0.01-2.0 wt % with respect to the amount of the conductive paste. When the amount of the inorganic fiber is less than 0.01 wt %, the shape-preservation effect after printing is poor. When the amount of the inorganic fiber exceeds 2.0 wt %, power generation is greatly reduced, and furthermore, an opening in the screen easily becomes clogged with paste, and print performance deteriorates. The metal fiber and the carbon fiber can be used together, and in such a case it is preferable to prepare the fibers such that the total content thereof falls within the aforementioned range.

The mean fiber diameter of the inorganic fiber used is preferably 50-500 nm, and is more preferably 100-200 nm. Furthermore, the average fiber length is preferably 1-50 μm and is more preferably 3-20 μm. If the fiber length is less than 1 μm, the ability to retain the silver powder and the glass frit, which are also contained materials, and the ability to retain a shape having a high aspect ratio deteriorates. Moreover, if 50 μm is exceeded, a mesh portion of the screen easily becomes clogged with paste, and consequently print performance deteriorates.

### (4) Additives

The additives can be added to the conductive paste. The conductive paste of the present invention could preferably further contain a metal oxide of one or more of the metals selected from Zn, Ag, Gd, Ce, Zr, Ti, Mn, Sn, Ru, Co, Fe, Cu and Cr. The conductive paste contains more preferably ZnO as an additive. The present invention of conductive paste could contain more preferably Ag₂O as an additive as well as ZnO. The particle size of the additional metal oxide additive is not subject to any particular limitation, although an average particle size of no more than 5 μm, and preferably no more than 2 μm, is desirable.

### (5) Organic Medium

The components of the paste are typically spread in an organic medium by mechanical mixing to form viscous compositions called “pastes”, having suitable consistency and rheology for applying such as printing or coating.

A wide variety of inert viscous materials can be used as organic medium. The organic medium is desired to be one in which the inorganic components are dispersible with an adequate degree of stability. The rheological properties of the medium is preferred to be such that they lend good application properties to the composition, including: stable dispersion of solids, appropriate viscosity and thixotropy for screen printing, appropriate wettability of the substrate and the paste solids, a good drying rate, and good firing properties.

The organic medium used in the conductive paste of the present invention is preferably a nonaqueous inert liquid. The organic medium may or may not contain thickeners, stabilizers and/or other common additives. The organic medium is typically a solution of polymer(s) in solvent(s). Additionally, a small amount of additives, such as surfactants, may be a part of the organic medium.

The most frequently used polymer for this purpose is ethyl cellulose. Other examples of polymers include ethylhydroxyethyl cellulose, wood rosin, mixtures of ethyl cellulose and phenolic resins, polymethacrylates of lower alcohols, and monobutyl ether of ethylene glycol monoacetate can also be used.

The most widely used solvents found in conductive pastes are ester alcohols and terpenes such as alpha or beta terpineol or mixtures thereof with other solvents such as kerosene, dibutylphthalate, butyl carbitol, butyl carbitol acetate, hexylene glycol and high boiling alcohols and alcohol esters.

In addition, volatile liquids for promoting rapid hardening after application on the substrate can be included in the medium. Various combinations of these and other solvents are formulated to obtain the viscosity and volatility requirements desired.

The polymer present is preferably in the range of 2 to 25 wt % of the organic medium. The solvent is preferably in the range of 70 to 98 wt % of the organic medium. The ratio of organic medium in the conductive paste to the inorganic components in the dispersion is dependent on the method of applying the paste and the kind of organic medium used, and it can vary. Usually, the dispersion will contain 70-90 wt % of inorganic components and 10-30 wt % of organic medium in order to obtain good wetting.

An electrode having a high aspect ratio can be formed according to the present invention. The specific aspect ratio (width:thickness) of the electrode is not particularly limited, but is preferably 1:0.25 or more and is more preferably 1:0.30 or more. The maximum is not particularly limited, but about 1:1 is practical.

The invention provides a novel electrode. FIG. 1A shows a step in which a substrate of single-crystal silicon or of multicrystalline silicon is provided typically, with a textured surface which reduces light reflection. In the case of solar cells, substrates are often used as sliced from ingots which have been formed from pulling or casting processes. Substrate surface damage caused by tools such as a wire saw used for slicing and contamination from the wafer slicing step are typically removed by etching away about 10 to 20 μm of the substrate surface using an aqueous alkali solution such as aqueous potassium hydroxide or aqueous sodium hydroxide, or using a mixture of hydrofluoric acid and nitric acid. In addition, a step in which the substrate is washed with a mixture of hydrochloric acid and hydrogen peroxide may be added to remove heavy metals such as iron adhering to the substrate surface. An antireflective textured surface is sometimes formed thereafter using, for example, an aqueous alkali solution such as aqueous potassium hydroxide or aqueous sodium hydroxide. This gives the substrate, 10.

Next, referring to FIG. 1B, when the substrate used is a p-type substrate, an n-type layer is formed to create a p-n junction. The method used to form such an n-type layer may be phosphorus (P) diffusion using phosphorus oxychloride (POCl₃). The depth of the diffusion layer in this case can be varied by controlling the diffusion temperature and time, and is generally formed within a thickness range of about from 0.1 to 0.5 μm. Especially when the emitter junction depth is from 0.1 μm to 0.3 μm, it is called Shallow-emitter type Solar cell. The n-type layer formed in this way is represented in the diagram by reference numeral 20.

Next, p-n separation on the front and backsides may be carried out by the method described in the background of the invention. These steps are not always necessary when a phosphorus-containing liquid coating material such as phosphosilicate glass (PSG) is applied onto only one surface of the substrate by a process, such as spin coating, and diffusion is effected by annealing under suitable conditions. Of course, where there is a risk of an n-type layer forming on the backside of the substrate as well, the degree of completeness can be increased by employing the steps detailed in the background of the invention.

After protecting one surface of this diffusion layer with a resist or the like, as shown in FIG. 1C, the diffusion layer, 20, is removed from most surfaces by etching so that it remains only on one main surface. The resist is then removed using an organic solvent or the like.

Next, in FIG. 1D, a silicon nitride film or other insulating films including SiNx:H (i.e., the insulating film comprises hydrogen for passivation during subsequent firing processing) film, titanium oxide film, and silicon oxide film, 30, which functions as an antireflection coating is formed on the above-described n-type diffusion layer, 20. This silicon nitride film, 30, lowers the surface reflectance of the solar cell to incident light, making it possible to greatly increase the electrical current generated. The thickness of the silicon nitride film, 30, depends on its refractive index, although a thickness of about 700 to 900 Å is suitable for a refractive index of about 1.9 to 2.0.

This silicon nitride film may be formed by a process such as low-pressure CVD, plasma CVD, or thermal CVD. When thermal CVD is used, the starting materials are often dichlorosilane (SiCl₂H₂) and ammonia (NH₃) gas, and film formation is carried out at a temperature of at least 700° C. When thermal CVD is used, pyrolysis of the starting gases at the high temperature results in the presence of substantially no hydrogen in the silicon nitride film, giving a compositional ratio between the silicon and the nitrogen of Si₃N₄ which is substantially stoichiometric. The refractive index falls within a range of substantially 1.96 to 1.98. Hence, this type of silicon nitride film is a very dense film whose characteristics, such as thickness and refractive index, remain unchanged even when subjected to heat treatment in a later step.

In FIG. 1D, a titanium oxide film may be formed on the n-type diffusion layer, 20, instead of the silicon nitride film, 30, functioning as an antireflection coating. The titanium oxide film is formed by coating a titanium-containing organic liquid material onto the n-type diffusion layer, 20, and firing, or by thermal CVD. It is also possible, in FIG. 1D, to form a silicon oxide film on the n-type diffusion layer, 20, instead of the silicon nitride film 30 functioning as an antireflection layer. The silicon oxide film is formed by thermal oxidation, thermal CVD or plasma CVD.

Next, electrodes are formed by steps similar to those shown in FIG. 1E and FIG. 1F. That is, as shown in FIG. 1E, aluminum paste, 60, and back side silver paste, 70, are screen printed onto the back side of the substrate, 10, as shown in FIG. 1E and successively dried. In addition, a front electrode-forming conductive paste is screen printed onto the silicon nitride film, 30, in the same way as on the back side of the substrate, 10, following which drying and firing are carried out in an infrared furnace typically at a set point temperature range of 580 to 975° C. for a period of from one minute to more than ten minutes while passing through the furnace a mixed gas stream of oxygen and nitrogen.

As shown in FIG. 1F, during firing, aluminum diffuses as an impurity from the aluminum paste into the silicon substrate, 10, on the back side, thereby forming a p+ layer, 40, containing a high aluminum dopant concentration. Firing converts the dried aluminum paste, 60, to an aluminum back electrode, 61. The backside silver paste, 70, is fired at the same time, becoming a silver back electrode, 71. During firing, the boundary between the backside aluminum and the backside silver assumes the state of an alloy, thereby achieving electrical connection. Most areas of the back electrode are occupied by the aluminum electrode, partly on account of the need to form a p+ layer, 40. At the same time, because soldering to an aluminum electrode is impossible, the silver or silver/aluminum back electrode is formed on limited areas of the backside as an electrode for interconnecting solar cells by means of copper ribbon or the like.

On the front side, the front electrode, 500, is made of the conductive paste of the present invention, and is capable of reacting and penetrating through the silicon nitride film, 30, during firing to achieve electrical contact with the n-type layer, 20 (fire through). This fired-through state, i.e., the extent to which the conductive paste on the front melts and passes through the silicon nitride film, 30, depends on the quality and thickness of the silicon nitride film, 30, the composition of the front electrode, and on the firing conditions. The conversion efficiency and moisture resistance reliability of the solar cell clearly depend, to a large degree, on this fired-through state.

A conductive paste for solar cell electrode of this present invention can be used on not only p-type base solar cell but also any type of silicon solar cell such as n-type base solar cell.

### EXAMPLES

Examples of the electrode of the present invention are described herein below.

### (A) Conductive Paste Preparation

Used material in the paste preparation and the content of each component are as follows:
I. Electrically functional conductive powder: A mixture of 24% of spherical silver powder [d50 2.3 μm as determined with a laser scattering-type particle size distribution measuring apparatus] and 56% of flake silver powder [d50 2.9 μm] were used. The total content of the silver powder was 80 wt % of the conductive paste.
II. Glass Frit: Si—Pb—B based glass frit was used. The total content of the glass frit was adjusted depending on the content of the inorganic fiber as shown in Table 1.
III. Organic Medium: An organic medium consisting of mainly Ethyl cellulose resin and texanol was used. The content of the organic medium was 10 wt % of the conductive paste.
IV. Inorganic fiber: A carbon fiber (VGCF-H, Showa Denko K. K.) having a diameter of 150 nm, a length of 6 μm, and a bulk density 0.08 g/cm³ was used. The amount of carbon fiber contained in the paste is shown in Table 1.
V. Additive: every conductive paste contained 5.8 wt % of ZnO as an additive.

Paste preparations were, in general, accomplished with the following procedure: The appropriate amount of solvent and the organic medium described above were weighed then mixed in a mixing can for 15 minutes, then silver powder, glass frit, and carbon fiber described above and ZnO as a metal additive were added and mixed for another 5 minutes. When well mixed, the paste was repeatedly passed through a 3-roll mill for at progressively increasing pressures from 0 to 400 psi. The gap of the rolls was adjusted to 1 mil.

TABLE 1

| | Conductive | | | |
|---|---|---|---|---|
| | powder | Glass frit | Fiber | Organic Medium |
| Ex. 1 | Ag | Si—Pb—B | VGCF | Ethyl cellulose and |
| | (80 wt %) | (9.9 wt %) | (0.1 wt %) | texanol |
| | | | | (10 wt %) |
| Ex. 2 | Ag | Si—Pb—B | VGCF | Ethyl cellulose and |
| | (80 wt %) | (9.5 wt %) | (0.5 wt %) | texanol |
| | | | | (10 wt %) |
| Ex. 3 | Ag | Si—Pb—B | VGCF | Ethyl cellulose and |
| | (80 wt %) | (9.0 wt %) | (1.0 wt %) | texanol |
| | | | | (10 wt %) |
| Com. | Ag | Si—Pb—B | None | Ethyl cellulose and |
| Ex. 1 | (80 wt %) | (10 wt %) | | texanol |
| | | | | (10 wt %) |

### (B) Method of Electrode Forming

Solar cells were formed by using the conductive paste described in (A) above. Firstly, silicon (Si) wafers (p-doped base and n-doped emitter with SiNx antireflection coatings) were prepared. The sizes of the Si wafers were 38 mm square and 0.2 mm thickness. Aluminum paste (PV322 E.I. Dupont de Nemours and Company) was screen printed on the back side of these Si wafers and then dried at the temperature of 150° C. for 5 minutes. The printed pattern of aluminum paste was 34 mm×34 mm square and 30 μm thickness after drying. The conductive paste prepared in (A) was printed on front side of the Si wafer to form electrode pattern with a bus bar and seventeen finger lines at both side of the bus bar. The wafers with printed pattern were dried under 150° C. for 5 min. The dried pattern was fired in an IR heating belt furnace in air. The maximum set temperature was around 770° C. and its In-Out time was 115 sec.

### (C) Test Procedure Electrode Height (Aspect Ratio)

The electrode height (μm) was measured after firing with Confocal laser scanning microscopy, Model OPTELICS C130, Lasertec Corporation.

### (D) Results

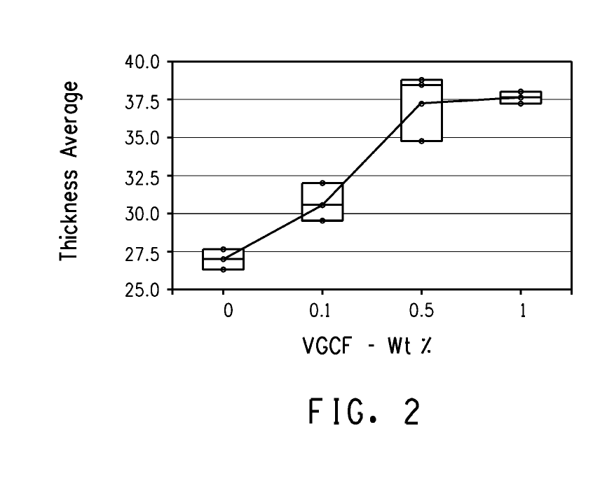

Table 2 shows the heights of the electrodes after firing, the electrodes having been formed using conductive pastes containing different quantities of carbon fiber. As shown in Table 2, use of a fiber clearly can improve the aspect ratio. FIG. 2 shows a box plot showing the relationship between the amount of fiber contained and the height of the formed electrode.

TABLE 2

| | VGCF (wt %) | (μm) | aspect ratio |
|---|---|---|---|
| Example 1 | 0.1 | 31.0 | 0.33 |
| Example 2 | 0.5 | 37.3 | 0.38 |
| Example 3 | 1.0 | 37.5 | 0.36 |
| Comparison 1 | 0 | 27.0 | 0.26 |

What is claimed is:

1. An electrode formed on the light-receiving side of photovoltaic cell, comprising conductive component, glass binder, and carbon fiber or metal fiber.

2. An electrode according to claim 1, wherein the aspect ratio of the electrode width:thickness is 1:0.25-1:1.

3. An electrode according to claim 1, wherein the carbon fiber is vapor grown carbon fiber.

4. An electrode according to claim 1, wherein the average length of the carbon fiber is 1-50 μm and the average diameter of the carbon fiber is 50-500 μm.

5. An electrode according to claim 1, wherein the content of the carbon fiber is 0.01-2.0 wt % based on the total weight of the electrode.

6. A method for forming an electrode of photovoltaic cell, comprising steps of:
applying a conductive paste on the light-receiving side of a silicon wafer, the conductive paste comprising conductive powder, glass frit, carbon fiber or metal fiber, and organic medium;
drying the applied paste; and
firing the dried paste.

7. A method according to claim 6, wherein the conductive paste comprises 70-96 wt % of the conductive powder, 0.5 to 15.0 wt % of the glass frit, 0.01-2.0 wt % of carbon fiber or metal fiber, and 2-25 wt % of the organic medium based on the weight of the conductive paste.
